(19) United States
(12) Patent Application Publication
(10) Pub. No.: US 2017/0316730 A1
(43) Pub. Date: Nov. 2, 2017

(54) DISPLAY PANELS WITH A GATE DRIVER CIRCUIT DISPOSED IN THE ACTIVE AREA THEREOF

(71) Applicant: InnoLux Corporation, Miao-Li County (TW)

(72) Inventors: Chang-Chiang CHENG, Miao-Li County (TW); Chien-Hsueh CHIANG, Miao-Li County (TW); Bo-Feng CHEN, Miao-Li County (TW)

(21) Appl. No.: 15/487,495

(22) Filed: Apr. 14, 2017

(30) Foreign Application Priority Data
Apr. 29, 2016 (TW) 105113408

(51) Int. Cl. G09G 3/20; G06F 3/041; H01L 27/12

(52) U.S. Cl. CPC G09G 3/2092; G06F 3/041; G09G 2310/0232; H01L 27/124; G09G 2310/08

(57) ABSTRACT

A display panel includes a substrate, multiple data lines, multiple gate lines, a power line and a gate driver circuit. The power line is coupled to a power source. The gate driver circuit is disposed in an active area of the substrate and is coupled to the gate lines and the power line. The gate driver circuit generates multiple gate driving signals in response to a start pulse. The gate lines include a first metal layer disposed above the substrate. The data lines include a second metal layer disposed above the first metal layer. The power line includes a third metal layer disposed above the second metal layer. An orthogonal projection of at least one of the data lines onto the substrate overlaps an orthogonal projection of the power line onto the substrate.

### CROSS REFERENCE TO RELATED APPLICATIONS

This Application claims priority of Taiwan Patent Application No. 105113408, filed on Apr. 29, 2016, the entirety of which is incorporated by reference herein.

### BACKGROUND

### Field of the Disclosure

The disclosure relates to a display panel, and more particularly to a display panel with a gate driver circuit disposed in the active area thereof.

### Description of the Related Art

Driver circuits are important elements of display devices. Conventionally, the driver chip is used as the driver circuit of the display device. Integrated gate driver circuit technology has recently been developed, in which the gate driver circuit is formed on the panel. This technology is also called Gate driver on panel (GOP).

Generally, with integrated gate driver circuit technology, the GOP circuit is integrated in the border area at two sides of the substrate. However, this implementation occupies space in the border area of the panel. Therefore, the width of the border area cannot be reduced. In today's consumer products such as mobile phones, wearable devices, and vehicle dashboard instrument panels, border designs that are extra-slim and non-rectangular are becoming more and more popular. However, it is hard to implement extra-slim and non-rectangular border designs using a display device with a GOP circuit integrated into the border area.

Therefore, a novel circuit design and layout of a display device that can achieve an extra-slim border design are required.

### BRIEF SUMMARY OF THE DISCLOSURE

Display panels are provided. An exemplary embodiment of a display panel comprises a substrate, a plurality of data lines, a plurality of gate lines, a power line and a gate driver circuit. The power line is coupled to a power source. The gate driver circuit is disposed in an active area of the substrate and coupled to the gate lines and the power line, and generates a plurality of gate driving signals in response to a start pulse. The gate lines comprise a first metal layer which is disposed above the substrate. The data lines comprise a second metal layer which is disposed above the first metal layer. The power line comprises a third metal layer which is disposed above the second metal layer. An orthogonal projection of at least one of the data lines onto the substrate overlaps an orthogonal projection of the power line onto the substrate.

Another exemplary embodiment of a display panel comprises a substrate, a plurality of gate lines, a plurality of data lines, a plurality of clock signal lines and a gate driver circuit. The clock signal lines provide a plurality of clock signals. The gate driver circuit is disposed in an active area of the substrate, is coupled to the gate lines and the clock signal lines, and generates a plurality of gate driving signals in response to a start pulse. The gate lines and the clock signal lines comprise a first metal layer which is disposed above the substrate, the data lines comprise a second metal layer which is disposed above the first metal layer, and the gate lines and the clock signal lines are parallel.

A detailed description is given in the following embodiments with reference to the accompanying drawings.

### BRIEF DESCRIPTION OF DRAWINGS

The disclosure can be more fully understood by reading the subsequent detailed description and examples with references made to the accompanying drawings, wherein:

FIG. 1 is a block diagram of a display device according to an embodiment of the disclosure;

FIG. 2 is a circuit diagram of the gate driver circuit disposed in the active area of the display panel according to an embodiment of the first aspect of the disclosure;

FIG. 3 shows an exemplary top view of an electronic device according to an embodiment of the disclosure;

FIG. 4 is a block diagram of an n-th stage driving unit according to an embodiment of the disclosure, where n is a positive integer and 0<n≦N;

FIG. 5 shows a circuit diagram of a plurality of stages of driving units according to a first embodiment of the first aspect of the disclosure;

FIG. 6 is a diagram showing signal waveforms according to an embodiment of the disclosure;

FIG. 7 shows an exemplary top view of the layout of a portion of the pixel array according to an embodiment of the disclosure;

FIG. 8A shows an exemplary perspective view of the layout of a portion of the pixel array according to an embodiment of the disclosure;

FIG. 8B shows an exemplary sectional view of the layout of the driving unit circuit area in the active area of the display panel according to an embodiment of the disclosure;

FIG. 9A shows an exemplary top view of an electronic device according to an embodiment of the disclosure;

FIG. 9B shows an exemplary sectional view of the layout of the non-driving unit circuit area in the active area of the display panel according to an embodiment of the disclosure;

FIG. 10A shows a circuit diagram of a plurality of stages of driving units according to a second embodiment of the first aspect of the disclosure;

FIG. 10B shows a circuit diagram of a plurality of stages of driving units according to a third embodiment of the first aspect of the disclosure;

FIG. 11A is a schematic diagram of a gate driver circuit according to a fourth embodiment of the first aspect of the disclosure;

FIG. 11B is a diagram showing signal waveforms according to the fourth embodiment of the first aspect of the disclosure;

FIG. 12 is a block diagram of an n-th stage driving unit according to an embodiment of the second aspect of the disclosure;

FIG. 13A shows a circuit diagram of a plurality of stages of driving units according to a first embodiment of the second aspect of the disclosure;

FIG. 13B is a diagram showing signal waveforms according to the first embodiment of the second aspect of the disclosure;

FIG. 14A shows a circuit diagram of a plurality of stages of driving units according to a second embodiment of the second aspect of the disclosure;

FIG. 14B is a diagram showing signal waveforms according to the second embodiment of the second aspect of the disclosure;

FIG. 15A shows a circuit diagram of a plurality of stages of driving units according to a third embodiment of the second aspect of the disclosure;

FIG. 15B shows a circuit diagram of a plurality of stages of driving units according to a fourth embodiment of the second aspect of the disclosure;

FIG. 16A is a diagram showing signal waveforms according to the sixth embodiment of the second aspect of the disclosure;

FIG. 16B is another diagram showing signal waveforms according to the sixth embodiment of the second aspect of the disclosure;

FIG. 16C is yet another diagram showing signal waveforms according to the sixth embodiment of the second aspect of the disclosure;

FIG. 17 is a circuit diagram of the gate driver circuit disposed in the active area of the display panel according to another embodiment of the disclosure;

FIG. 18 shows another exemplary top view of the layout of a portion of the pixel array according to another embodiment of the disclosure;

FIG. 19A is an exemplary diagram showing the waveforms of the clock signal and the gate driving signal when the parasitic capacitance is small;

FIG. 19B is an exemplary diagram showing the waveforms of the clock signal and the gate driving signal when the parasitic capacitance is large;

FIG. 20 is a circuit diagram of the gate driver circuit according to a first embodiment of the third aspect of the disclosure;

FIG. 21 is an exemplary diagram showing the signal waveforms according to a first embodiment of the third aspect of disclosure; and

FIG. 22 shows an exemplary waveform of an undesired ripple in the gate driving signal.

### DETAILED DESCRIPTION OF THE DISCLOSURE

The following description is of the contemplated mode of carrying out the disclosure. This description is made for the purpose of illustrating the general principles of the disclosure and should not be taken in a limiting sense. The scope of the disclosure is determined by reference to the appended claims.

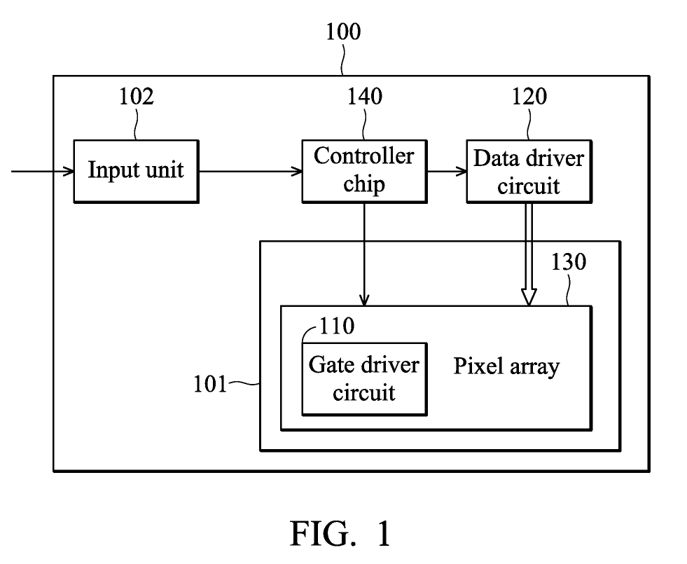

FIG. 1 is a block diagram of a display device according to an embodiment of the disclosure. As shown in FIG. 1, the display device 100 may comprise a display panel 101, a data driver circuit 120 and a controller chip 140. The display panel 101 may comprise a gate driver circuit 110 and a pixel array 130, wherein the gate driver circuit 110 is disposed in of the pixel array 130. The pixel array 130 may comprise a plurality of pixel units and each pixel unit is coupled to a pair of gate line and data line that crosses each other. The gate driver circuit 110 generates a corresponding gate driving signal on the gate lines to drive the pixel units in the pixel array 130. The data driver circuit 120 generates a corresponding data driving signal on the data lines to provide image data to the pixel units. The controller chip 140 generates a plurality of timing signals, comprising the clock signals, the reset signal, the start pulse, etc.

In addition, the display device 100 may further comprise an input unit 102. The input unit 102 receives image signals and outputs the adjusted/unadjusted image signals to the controller chip 140. According to an embodiment of the disclosure, the display device 100 may be applied in an electronic device. The electronic device may be implemented as various devices, comprising: a mobile phone, a digital camera, a personal digital assistant (PDA), a lap-top computer, a personal computer, a television, an in-vehicle display, a portable DVD player, or any apparatus with image display functionality.

Note that in some embodiments of the disclosure, the data driver circuit of the display panel may be integrated into the controller chip 140. In those embodiments of the disclosure, the image data may be provided to the pixel array 130 via the controller chip 140. Therefore, the structure shown in FIG. 1 is only one of a plurality of embodiments of the disclosure, and the disclosure should not be limited thereto.

Generally, the display panel comprises the active area (AA) and the border area(s), the border area is adjacent to the active area. According to an embodiment of the disclosure, the gate driver circuit 110 may be disposed in the active area (AA) of the substrate of the display panel. Details of a plurality of proposed gate driver circuits are discussed in the following paragraphs.

According to a first aspect of the disclosure, the components of the gate driver circuit 110 are disposed in the active area (AA) of the display panel 101.

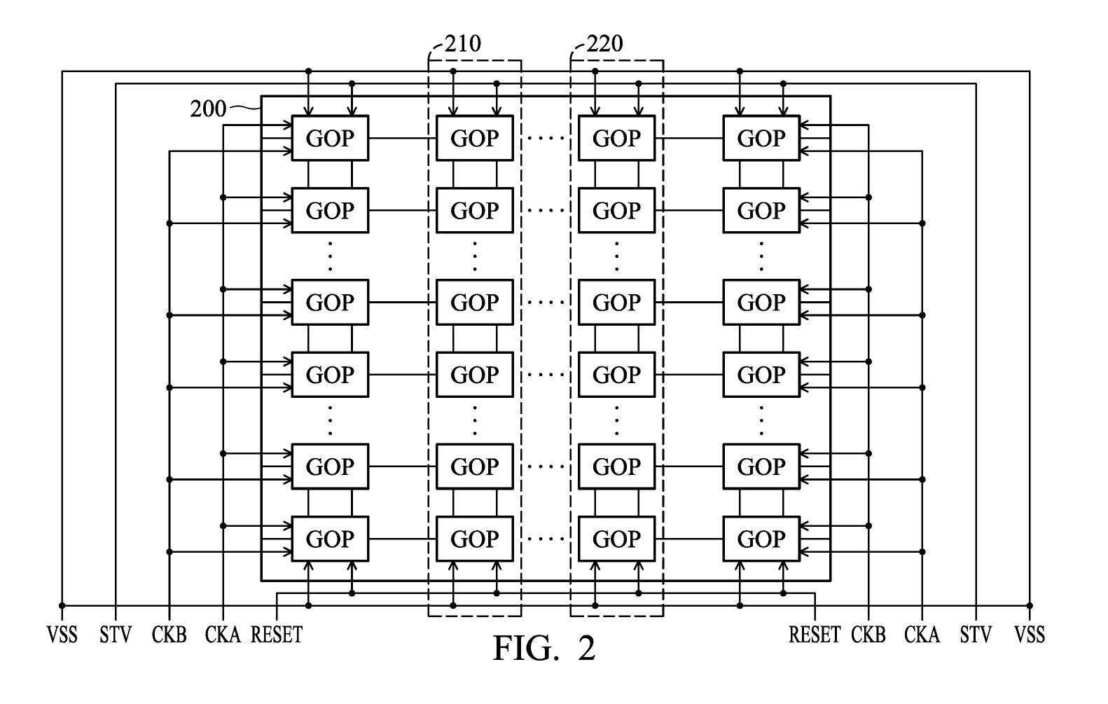

FIG. 2 is a circuit diagram of the gate driver circuit disposed in the active area of the display panel according to an embodiment of the first aspect of the disclosure. As shown in FIG. 2, the gate driver circuit may comprise a plurality of driving units GOP disposed in the active area 200 of the display panel. The gate driver circuit is coupled to at least one power line VSS and at least two clock signal lines CKA and CKB. The power line VSS is coupled to the power source for providing the reference voltage VGL required by the system. The clock signal lines CKA and CKB are coupled to the clock sources for providing at least two clock signals. The gate driver circuit receives the start pulse STV and the reset signal RESET via signal lines, and generates a plurality of gate driving signals in response to the start pulse STV. The last stage of the driving units is turned off in response to the reset signal RESET.

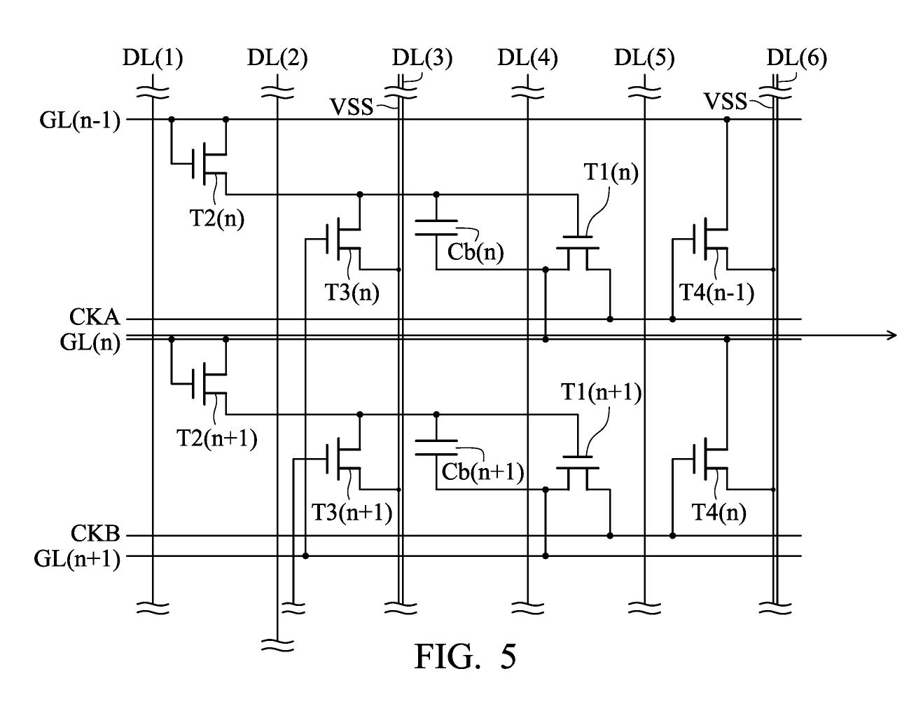

According to an embodiment of the disclosure, the driving units GOP may form an array, and one driving unit may be disposed among a plurality of data lines. Therefore, the layout of one driving unit may across a plurality of pixel units. For example, in an embodiment of the disclosure, as shown in FIG. 5, one driving unit may be disposed among 6 data lines. Therefore, the layout of one driving unit may cross 5 pixel units. In other words, according to an embodiment of the disclosure, the number of driving units configured for a row of pixel units is less than the number of data lines of the display panel. Note that in other embodiments of the disclosure, one driving unit may also be disposed among less than 6 or more than 6 data lines, and the disclosure should not be limited to any implementation method.

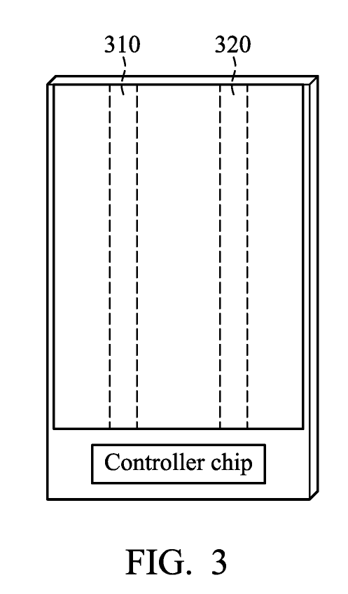

FIG. 3 shows an exemplary top view of an electronic device according to an embodiment of the disclosure, where the areas 310 and 320 framed by the dotted lines represents the driving unit circuit area of the gate driver circuit. The driving unit circuit areas 310 and 320 may correspond to the driving unit circuit areas 210 and 220 shown in FIG. 2 to show the relative positions of two columns of driving units of the gate driver circuit in active area of the display panel of the electronic device.

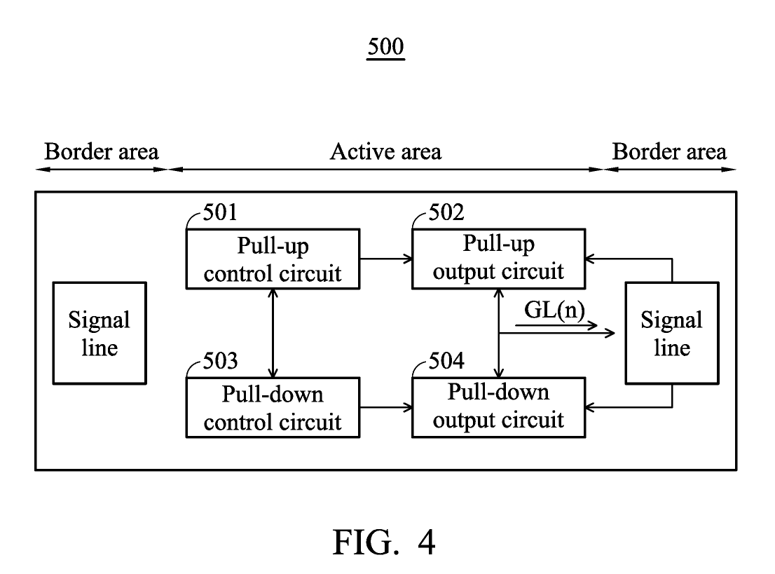

According to an embodiment of the disclosure, the gate driver circuit disposed in the active area of the display panel may comprise N stages of driving units, where N is a positive integer. FIG. 4 is a block diagram of an n-th stage driving unit according to an embodiment of the disclosure, where n is a positive integer and 0<n≦N. The driving unit 500 may comprise a pull-up control circuit 501, a pull-up output circuit 502, a pull-down control circuit 503 and a pull-down output circuit 504. The pull-up output circuit 502 and pull-down output circuit 504 are coupled to the n-th gate line GL(n) for controlling the output of the gate driving signal. As shown in FIG. 4, all the components of the driving unit 500 are disposed in the active area of the display panel, and the signal lines are configured in the border area of the display panel.

In the embodiments of the first aspect of the disclosure, since only the signal lines are left in the border areas, not only extra-slim border designs, but also non-rectangular border designs can be achieved.

FIG. 5 shows a circuit diagram of a plurality of stages of driving units according to a first embodiment of the first aspect of the disclosure. For simplicity, FIG. 5 shows only a portion of a column of driving units of the gate driver circuit, where the driving units as shown, such as the transistors T1(n), T1(n+1), T2(n), T2(n+1), T3(n), T3(n+1), T4(n−1) and T4(n) and the capacitors Cb(n) and Cb(n+1), are disposed among the data lines DL(1)-DL(6). Note that the data line numbers 1-6 of data lines D(1)-D(6) are only for illustrations, and the disclosure should not be limited thereto.

The transistor T1 corresponds to the pull-up output circuit of the driving unit in FIG. 4. The transistor T2 corresponds to the pull-up control circuit of the driving unit in FIG. 4. The transistor T3 corresponds to the pull-down control circuit of the driving unit in FIG. 4. The transistor T4 corresponds to the pull-down output circuit of the driving unit in FIG. 4. It should be understood that although the pull-up output circuit, the pull-up control circuit, the pull-down control circuit and the pull-down output circuit in the first embodiment of the first aspect of the disclosure respectively comprise one transistor as an example for illustration, the disclosure should not be limited thereto. In some other embodiments of the disclosure, those circuits may also respectively comprise more than one transistor.

According to an embodiment of the disclosure, the n-th stage driving unit may comprise transistors T1(n), T2(n), T3(n), T4(n) and capacitor Cb(n). The transistor T1(n) may comprise a first electrode coupled to a clock signal line CKA and a second electrode coupled to the n-th gate line GL(n). The transistor T2(n) may comprise a control electrode (also called as a gate electrode) and a first electrode coupled to the (n−1)-th gate line GL(n−1), and a second electrode coupled to a control electrode of the transistor T1(n). The transistor T3(n) may comprise a control electrode coupled to the (n+1)-th gate line GL(n+1), a first electrode coupled to the second electrode of the transistor T2(n) and a second electrode coupled to the power line VSS. The transistor T4(n) may comprise a control electrode coupled to a clock signal line CKB, a first electrode coupled to the (n)-th gate line GL(n) and a second electrode coupled to the power line VSS.

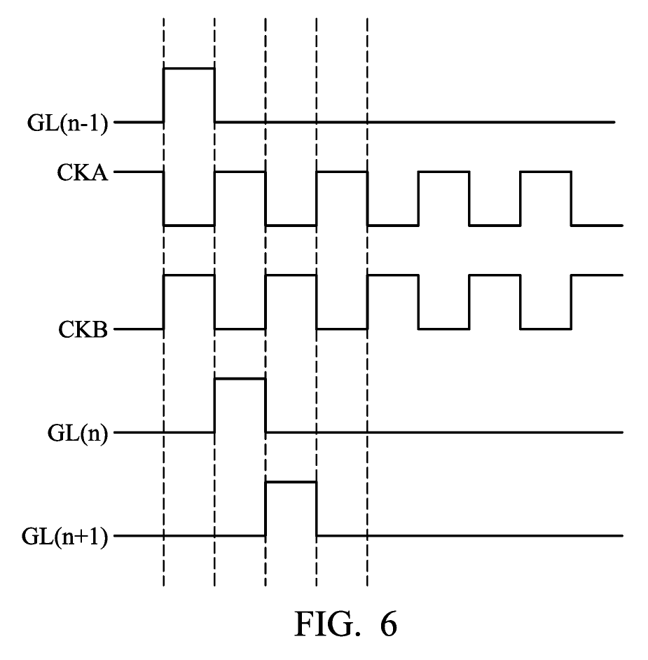

FIG. 6 is a diagram showing signal waveforms according to an embodiment of the disclosure. When the gate pulse on the gate line GL(n−1) arrives, the transistor T2(n) is turned on and then the transistor T1(n) is turned on. When the clock pulse on the clock signal line CKA arrives, the clock pulse is transmitted to the gate line GL(n) through the turned-on transistor T1(n) as the gate pulse of the gate line GL(n). When the gate pulse on the gate line GL(n+1) arrives, the transistor T3(n) is turned on to pull-down the voltage at the control electrode of the transistor T1(n), so as to turn off the transistor T1(n). Similarly, when the clock pulse on the clock signal line CKB arrives, the transistor T4(n) is turned on to pull-down the voltage on the n-th gate line GL(n).

As shown in FIG. 5, each stage of driving unit may only comprise four transistors. Therefore, compared to another driving unit design, which comprise at least thirteen transistors, the proposed gate driving circuit can effectively reduce the pixel's aspect ratio loss in the active area.

In addition, in the embodiments of the disclosure, to further reduce the pixel's aspect ratio loss in the active area, the layout of the signal lines in the circuit in the active area can be further designed.

According to a first embodiment of the disclosure, the gate lines of the display panel may comprise a first metal layer, the data lines may comprise a second metal layer, the power line VSS coupled to the power source may comprise a third metal layer. The first metal layer is formed above the substrate, the second metal layer is formed above the first metal layer and the third metal layer is formed above the second metal layer. The substrate may be the hard substrate or flexible substrate. The hard substrate may comprise glass, quartz, or sapphire. The flexible substrate may comprise plastic such as polycarbonate (PC), polyimide (PI), or polyethylene terephthalate (PET). However, the substrate is not limited to the above material. Since the data line and the power line comprise different metal layers, the data lines and the power line may spatially overlap (that is, an orthogonal projection of the data line and an orthogonal projection of the power line may overlap), so as to reduce the pixel's aspect ratio loss. In addition, according to a first embodiment of the disclosure, the clock signal lines comprise the first metal layer and the clock signal lines and the gate lines are substantially parallel. The connection points between different metal layers may be connected through the contact via. It should be noted that although in some embodiments of the disclosure the substrate is not shown, an orthogonal projection of an object means an orthogonal projection of the object onto the substrate. And the substrate may be a thin film transistor substrate where the gate driver circuit disposed thereon.

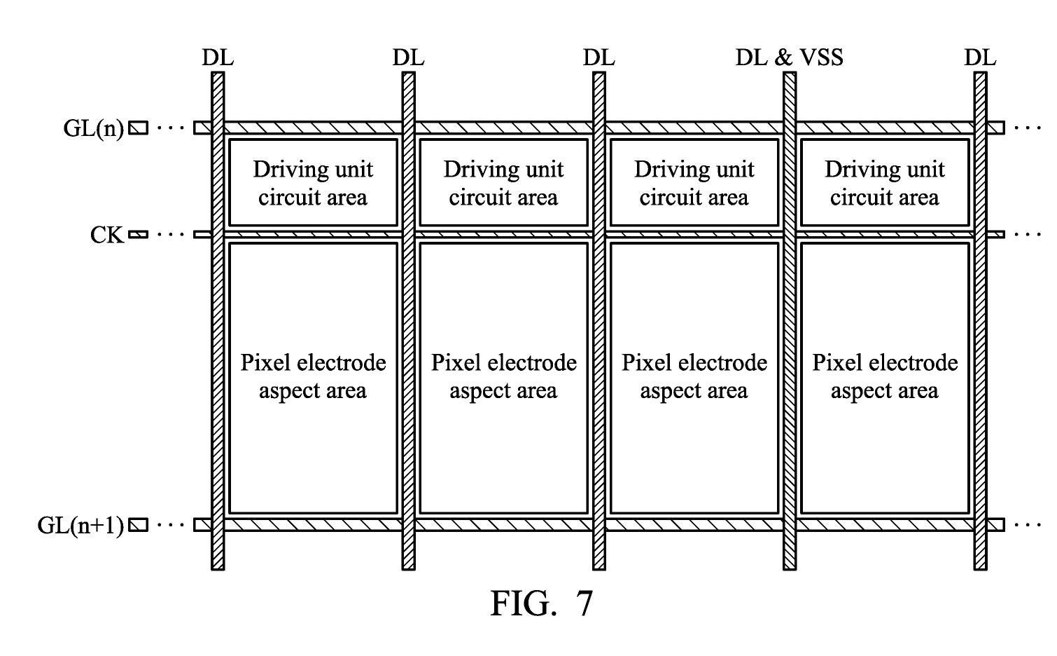

FIG. 7 shows an exemplary top view of the layout of a portion of the pixel array according to an embodiment of the disclosure. The clock signal line CK may represent any clock signal line of the disclosure. For example, the clock signal line CK may represent any of the clock signal lines CKA and CKB. The data line DL may represent any data line of the disclosure. For example, the data line DL may represent any of the data lines D(1)-D(6). As shown in the figure, the clock signal line CK and the gate lines GL(n) and GL(n+1) are parallel and an orthogonal projection of the data line DL overlaps an orthogonal projection of the power line VSS (therefore, the same line is used to represent the data line DL and the power line VSS in FIG. 7). The orthogonal projection of the data line DL may partially or completely overlap the orthogonal projection of the power line VSS. Further, if not particularly pointing out, “overlap” means partially or completely overlap in this disclosure.

As shown in FIG. 7, since there is no signal line passing through the aspect area of the pixel electrode, not only can a higher aspect ratio be obtained, such that the aspect ratios among the pixel units can be kept almost the same, but also undesired noise that causes poor picture quality, such as the vertical line or vertical band, can be effectively reduced.

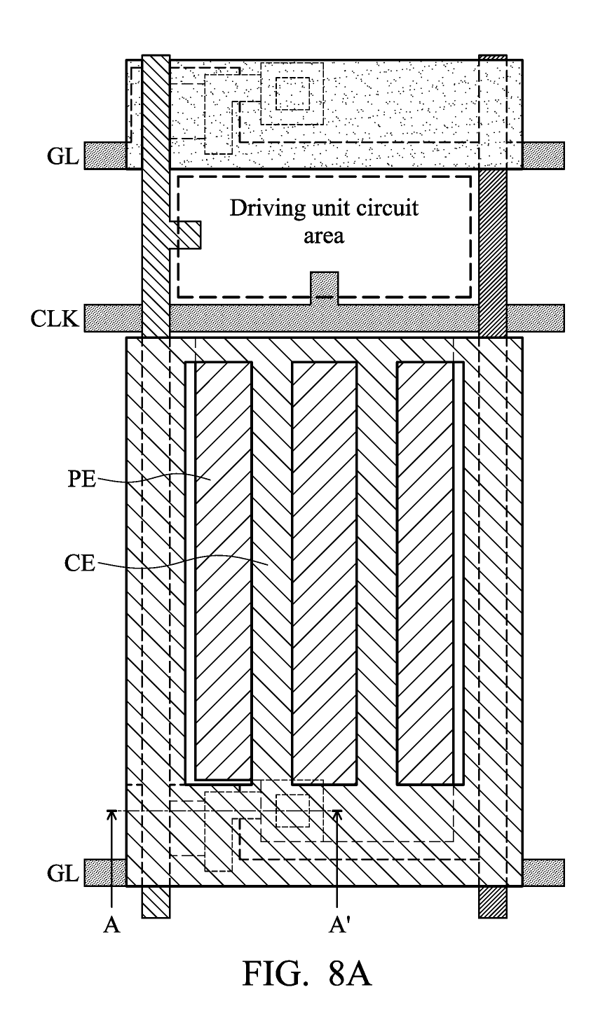

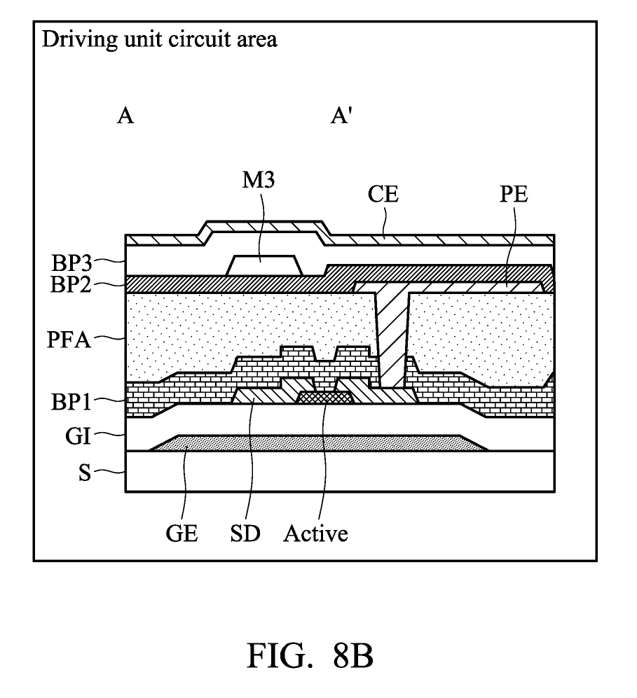

FIG. 8A shows an exemplary perspective view of the layout of a portion of the pixel array according to an embodiment of the disclosure. PE represents the pixel electrode, CE represents the common electrode. As shown in FIG. 8A, in the embodiments of the disclosure, the layouts of the clock signal line CLK and the pixel electrode PE do not overlap. Therefore, there will not be a coupling problem in the voltage of the pixel electrode.

FIG. 8B shows an exemplary sectional view of the layout of the driving unit circuit area in the active area of the display panel, which is the sectional view of the layout along a cross section line from the point A to the point A′ as shown in FIG. 8A, according to an embodiment of the disclosure. As shown in FIG. 8B, the metal layers are sequentially formed on the substrate S. GE represents the gate line which comprises the first metal layer. GI represents the gate insulator. SD represents the source/drain of the transistor which comprises the second metal layer. Active represents the active layer of the semiconductor. BP1, BP2 and BP3 represent the insulation layers. PFA represents the planarization layer. PE represents the pixel electrode. M3 represents the third metal layer. CE represents the common electrode. The materials of the pixel electrode PE and the common electrode CE may be transparent conducting oxides, such as the indium tin oxide (ITO), indium zinc oxide (IZO), fluorine doped tin oxide (FTO), aluminum doped zinc oxide (AZO) or gallium doped zinc oxide (GZO). According to an embodiment of the disclosure, because the power line VSS coupled to the power source comprises the third metal layer, in the driving unit circuit, the third metal layer is used to transmit the voltage signal of the voltage source.

Note that the layered manner of the layout shown in FIG. 8B is only one of a plurality of embodiments of the disclosure to illustrate the concept of the disclosure, and is not used to the limit the scope of the disclosure. For example, the exemplary embodiment is a bottom gate type transistor. In other embodiment, it can be replaced by a top gate type transistor.

In addition, the configuration of the third metal layer may also incorporate the in-cell touch application. The third metal layer may be connected to the common electrode CE to transmit the touch sense signal, improving the products' applicability and additional value.

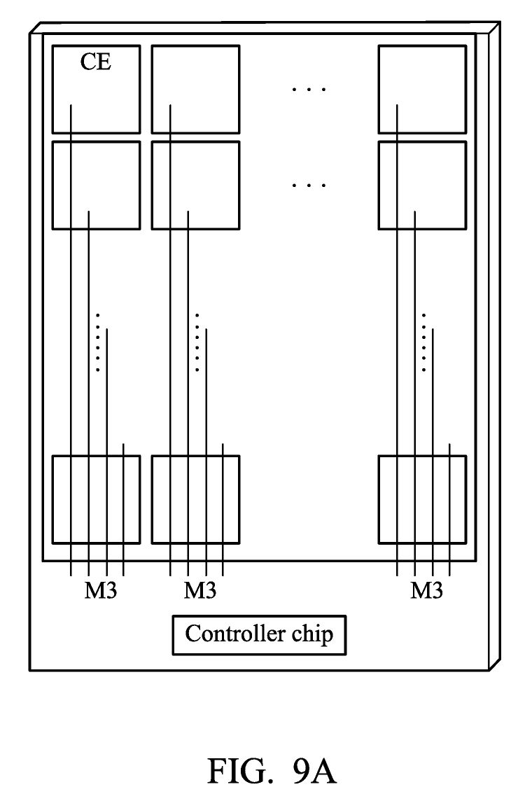

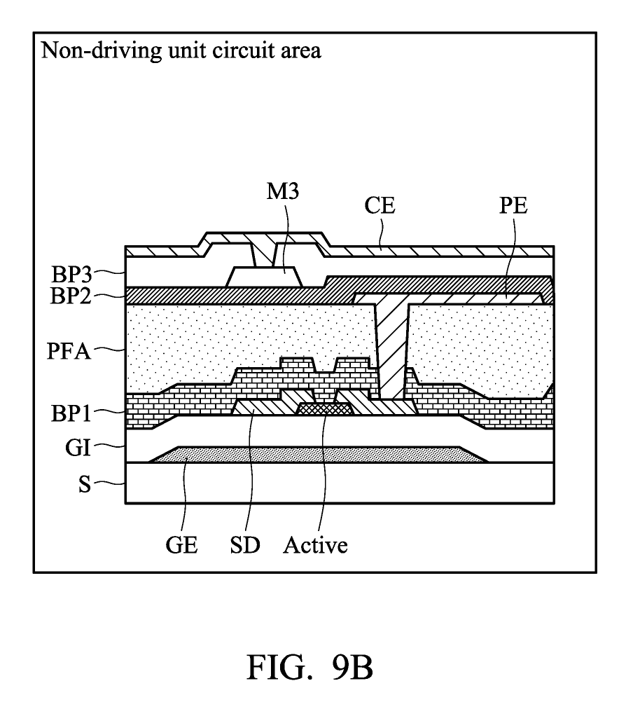

FIG. 9A shows an exemplary top view of an electronic device according to an embodiment of the disclosure. FIG. 9B shows an exemplary sectional view of the layout of the non-driving unit circuit area in the active area of the display panel according to an embodiment of the disclosure. As shown in FIG. 9A, the common electrode CE in the active area of the display panel may be used as the touch sensing electrode to sense the capacitance change. As shown in FIG. 9B, via the configuration of the third metal layer, in the non-driving unit circuit area, the third metal layer M3 is connected to the common electrode CE through the contact via.

As discussed above, in the first embodiment of the disclosure, the clock signal lines comprise the first metal layer and the clock signal lines and the gate lines are parallel. In some other embodiments of the disclosure, the clock signal lines may also comprise other metal layers.

According to a second embodiment of the disclosure, the gate lines of the display panel may comprise the first metal layer M1, the data lines may comprise the second metal layer M2, and the power line VSS coupled to the power source may comprise the third metal layer M3. The clock signal lines may comprise the second metal layer M2 and the clock signal lines and the data lines are parallel.

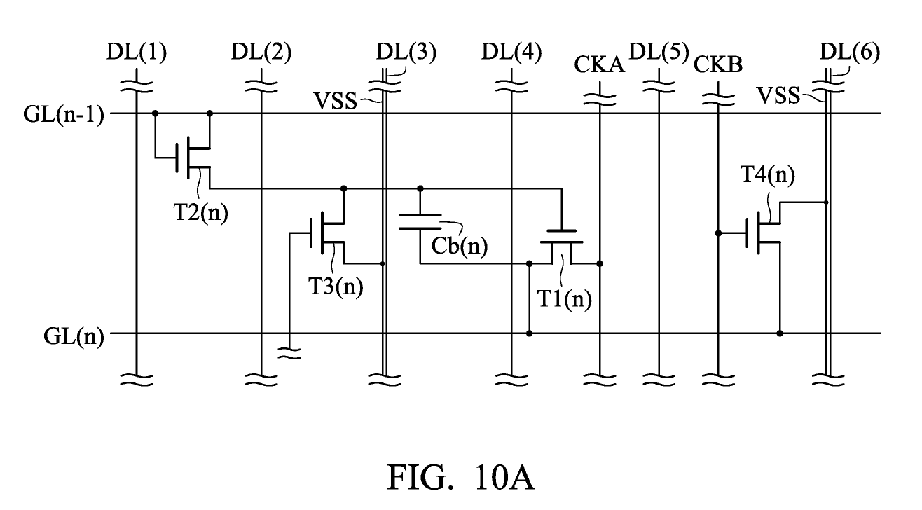

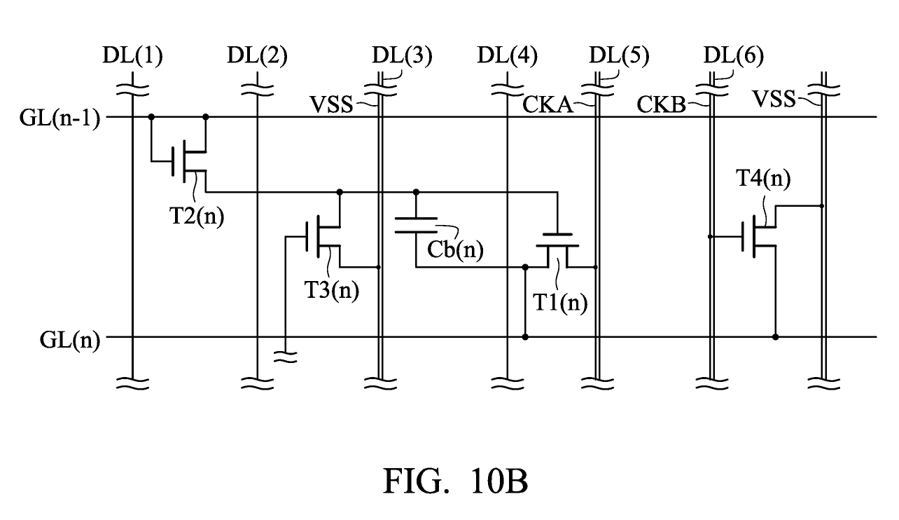

FIG. 10A shows a circuit diagram of a plurality of stages of driving units according to a second embodiment of the first aspect of the disclosure. For simplicity, FIG. 10A shows only a portion of driving units of the gate driver circuit. The data line numbers 1-6 of data lines D(1)-D(6) are only for illustration, and the disclosure should not be limited thereto.

As shown in FIG. 10A, clock signal lines CKA and CKB and the data lines are parallel and interleaved.

In addition, according to a third embodiment of the disclosure, the gate lines of the display panel may comprise the first metal layer M1, the data lines may comprise the second metal layer M2, and the power line VSS coupled to the power source may comprise the third metal layer M3. The clock signal lines may comprise the third metal layer M3 and the clock signal lines spatially overlap the data lines.

FIG. 10B shows a circuit diagram of a plurality of stages of driving units according to a third embodiment of the first aspect of the disclosure. For simplicity, FIG. 10B shows only a portion of driving units of the gate driver circuit. The data line numbers 1-6 of data lines D(1)-D(6) are only for illustration, and the disclosure should not be limited thereto.

As shown in FIG. 10B, the clock signal lines CKA and CKB and the power line VSS coupled to the power source are parallel and interleaved, and the clock signal lines CKA and CKB spatially overlap the data lines (that is, an orthogonal projection of the clock signal line and an orthogonal projection of the data line may overlap). Note that in order to show the connection points of the transistors and the clock signal lines and the connection points of the transistors and the power lines, in FIG. 5, FIG. 10A and FIG. 10B, the spatially overlapped data lines and power lines, or the spatially overlapped data lines and clock signal lines are drawn separately. However, it should be understood that when the data lines and the power lines, or the data lines and the clock signal lines comprise different metal layers, the layout of the lines can be spatially overlapped, such that the orthogonal projection thereof onto the substrate can overlap as shown in FIG. 7 and FIG. 8B. In addition, it should be noted that in other embodiments of the disclosure, the layout of the data lines, power lines and clock signal lines which comprise different metal layer may also not spatially overlap. Therefore, the layout of the disclosure should not be limited to the embodiments illustrated above.

According to a fourth embodiment of the disclosure, the number of clock signal lines can also be increased to reduce the duty cycle of the transistors in the driving unit.

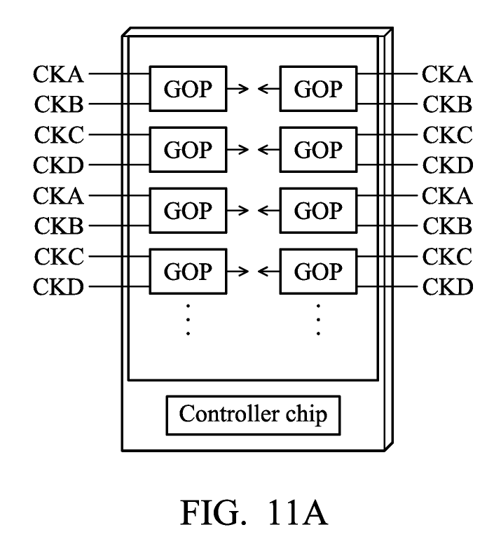

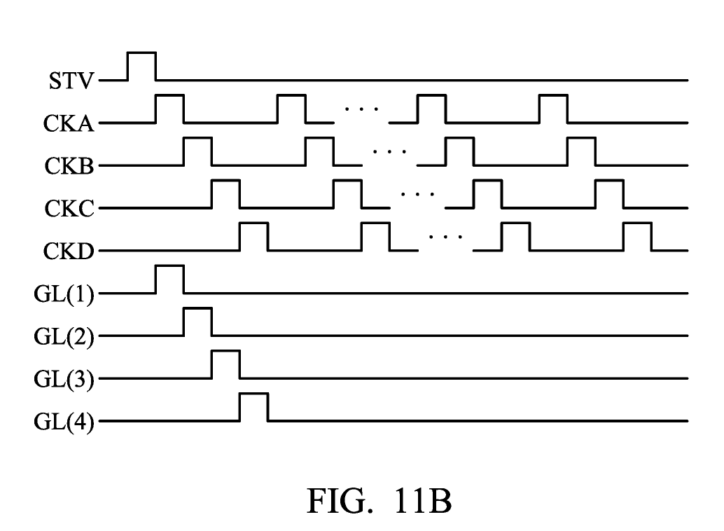

FIG. 11A is a schematic diagram of a gate driver circuit according to a fourth embodiment of the first aspect of the disclosure. As shown in FIG. 11A, each stage of driving unit in the gate driver circuit may be respectively coupled to the one of the clock signal lines CKA, CKB, CKC and CKD in sequence, and be repeated cyclically in this manner.

FIG. 11B is a diagram showing signal waveforms according to the fourth embodiment of the first aspect of the disclosure. As shown in FIG. 11B, when the start pulse arrives, the clock signal lines CKA, CKB, CKC and CKD provide non-overlapped clock pulses in sequence. Compared to the embodiments shown in FIG. 5 and FIG. 6, the duty cycle of the transistors (such as the transistors T1 and T4) in the driving unit may be reduced from 50% to 25%. In this manner, the time for the transistors to suffer from the stress of the bias voltage can be reduced, and the reliability of the circuit can be increased.

As discussed above, in the first aspect of the disclosure, all the components of the gate driver circuit 110 are disposed in the active area (AA) of the display panel 101. In the second aspect of the disclosure, some components of the gate driver circuit 110 are disposed in the border area of the display panel 101.

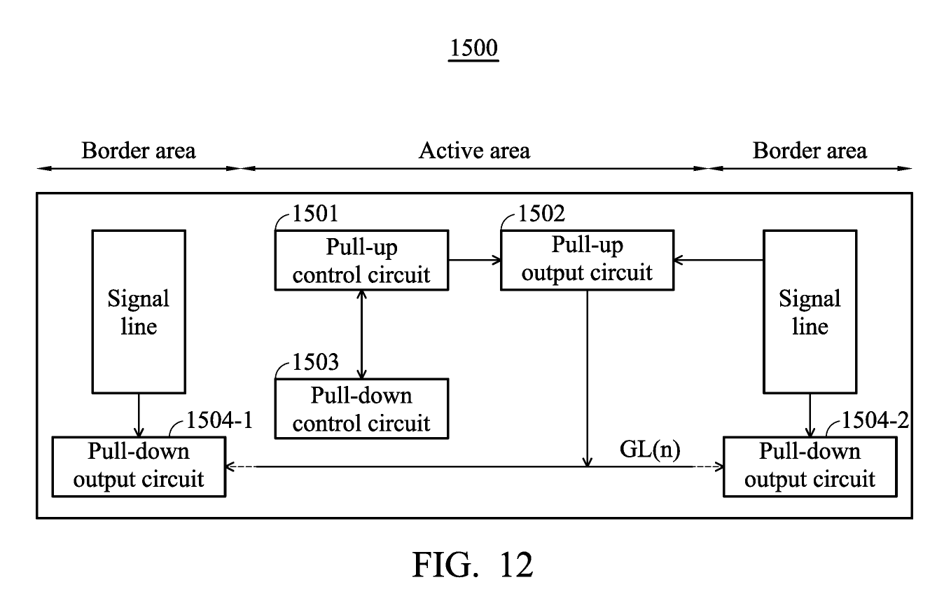

FIG. 12 is a block diagram of an n-th stage driving unit according to an embodiment of the second aspect of the disclosure, where n is a positive integer and 0<n≦N. The driving unit 1500 may comprise a pull-up control circuit 1501, a pull-up output circuit 1502, a pull-down control circuit 1503 and pull-down output circuits 1504-1 and 1504-2. The pull-up output circuit 1502 and pull-down output circuit 1504-1 and 1504-2 are coupled to the n-th gate line GL(n) for controlling the output of the gate driving signal. As shown in FIG. 12, the pull-down output circuit 1504-1 and 1504-2 and the signal lines are disposed in the border area of the display panel.

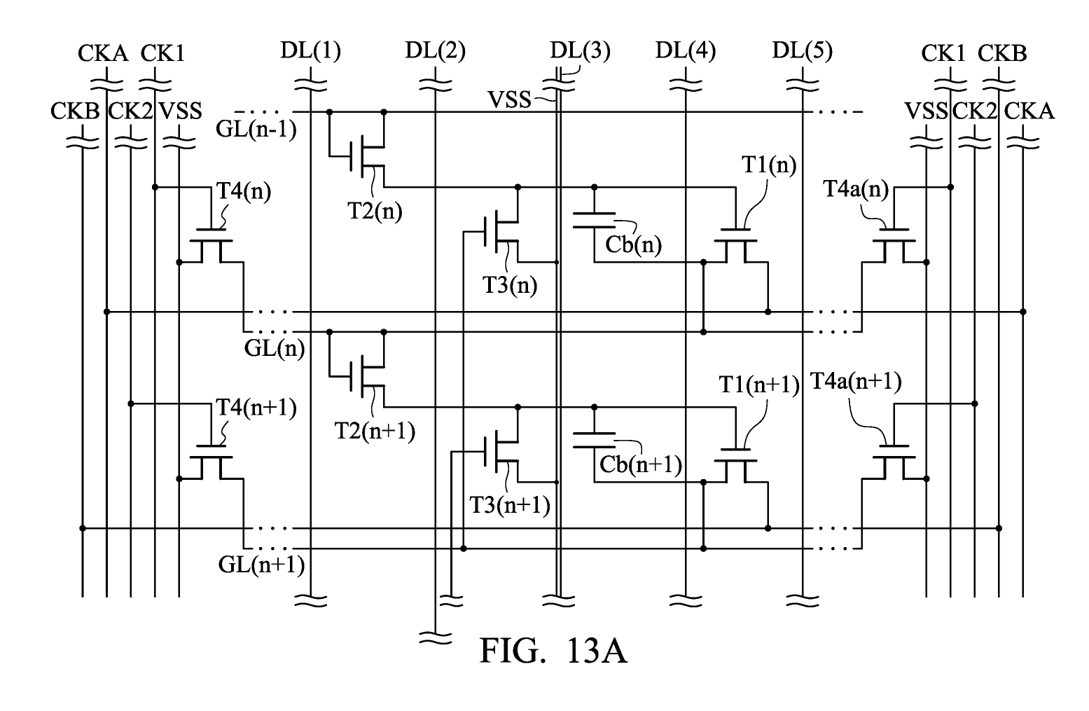

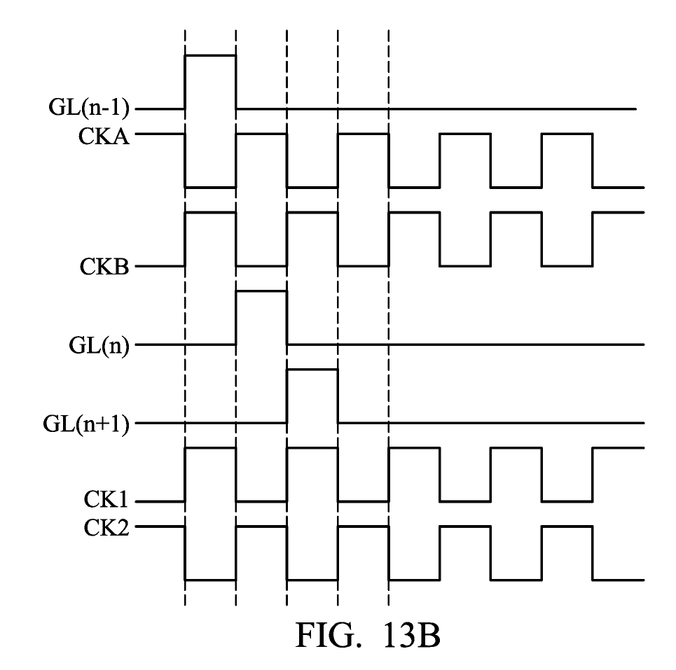

FIG. 13A shows a circuit diagram of a plurality of stages of driving units according to a first embodiment of the second aspect of the disclosure. The transistor T1 corresponds to the pull-up output circuit of the driving unit in FIG. 12. The transistor T2 corresponds to the pull-up control circuit of the driving unit in FIG. 12. The transistor T3 corresponds to the pull-down control circuit of the driving unit in FIG. 12. The transistors T4 and T4a correspond to the pull-down output circuits of the driving unit in FIG. 12. It should be understood that although the pull-up output circuit, the pull-up control circuit, the pull-down control circuit and the pull-down output circuits in the first embodiment of the second aspect of the disclosure respectively comprise one transistor as an example for illustration, the disclosure should not be limited thereto. In some other embodiments of the disclosure, those circuits may also respectively comprise more than one transistor. In addition, for simplicity, FIG. 13A shows only a portion of driving units of the gate driver circuit, where the portion of the driving units, such as the transistors T1(n), T1(n+1), T2(n), T2(n+1), T3(n), T3(n+1) and the capacitors Cb(n) and Cb(n+1) are disposed among the data lines DL(1)-DL(5). The remaining components, such as the transistors T4(n), T4(n+1), T4a(n) and T4a(n+1) are disposed in the border area. Note that the data line numbers 1-5 of data lines D(1)-D(5) are only for illustration, and the disclosure should not be limited thereto.

According to an embodiment of the disclosure, the n-th driving unit may comprise transistors T1(n), T2(n), T3(n), T4(n), T4a(n) and the capacitor Cb(n). The connection between the transistors T1(n)-T3(n) and the capacitor Cb(n) are the same as the embodiments shown in FIG. 5, and thus the descriptions are omitted here for brevity. In the embodiment, the transistors T4(n) and T4a(n) respectively comprise a control electrode coupled to the clock signal line CK1, a first electrode coupled to the n-th gate line GL(n) and a second electrode coupled to the power line VSS.

FIG. 13B is a diagram showing signal waveforms according to the first embodiment of the second aspect of the disclosure. When the gate pulse on the gate line GL(n−1) arrives, the transistor T2(n) is turned on and then the transistor T1(n) is turned on. When the clock pulse on the clock signal line CKA arrives, the clock pulse is transmitted to the gate line GL(n) through the turned-on transistor T1(n) as the gate pulse of the gate line GL(n). When the gate pulse on the gate line GL(n+1) arrives, the transistor T3(n) is turned on to pull-down the voltage at the control electrode of the transistor T1(n), so as to turn off the transistor T1(n). Similarly, when the clock pulse on the clock signal line CK1 arrives, the transistors T4(n) and T4a(n) are turned on to pull-down the voltage on the n-th gate line GL(n).

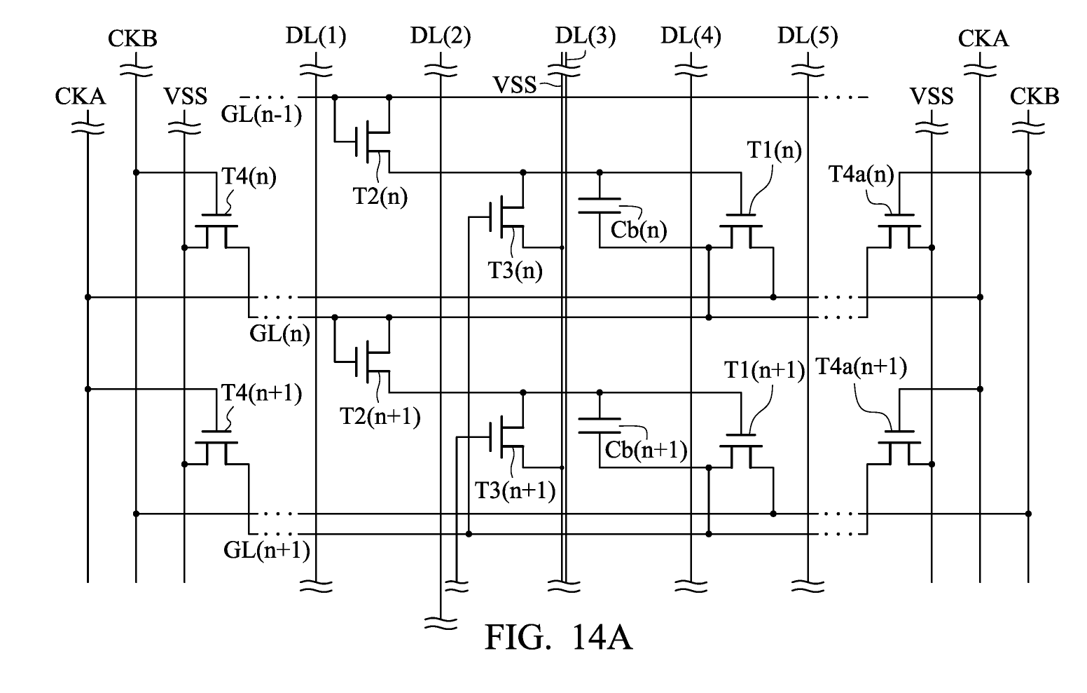

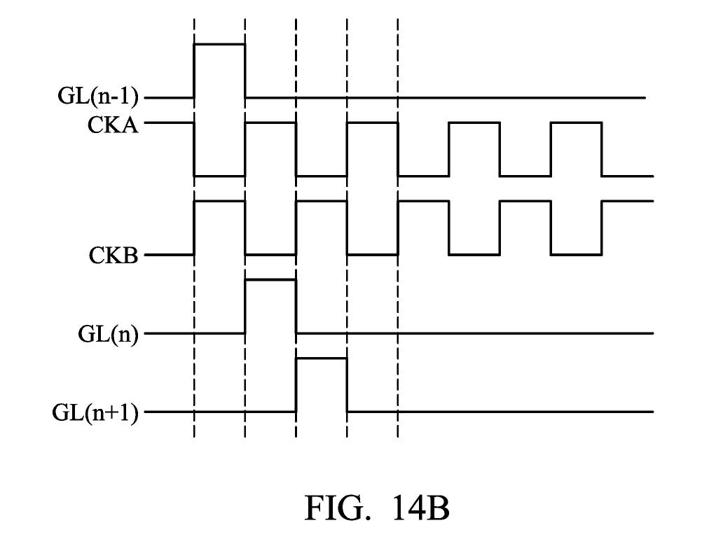

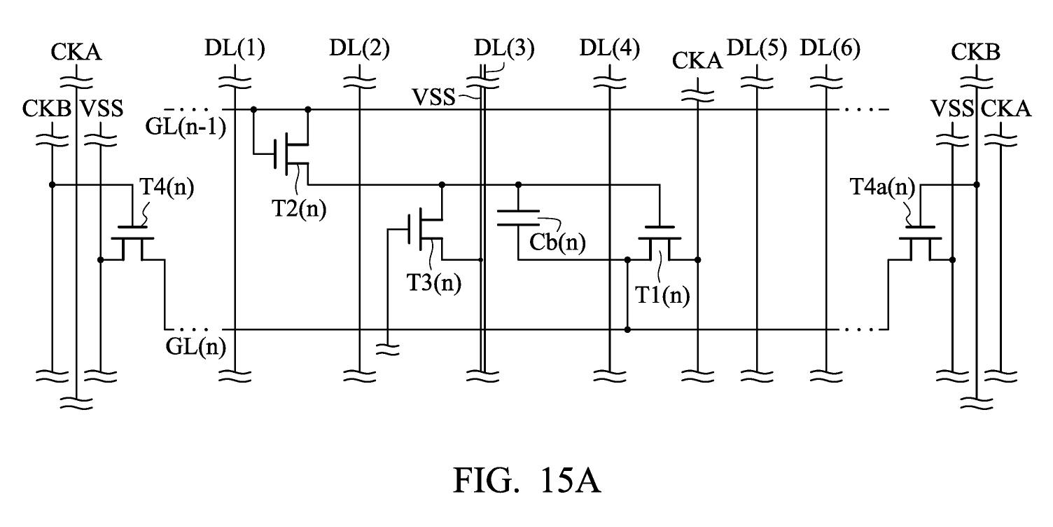

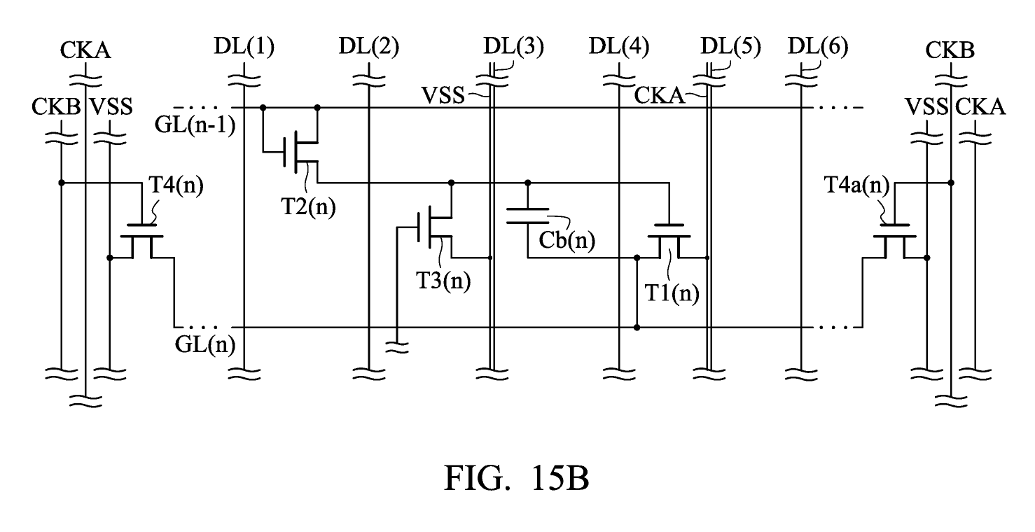

Note that although in the circuit shown in FIG. 13A, two clock signal lines CK1 and CK2 are added for providing clock signals to the transistors T4(n) and T4a(n) in the border area, the disclosure should not be limited thereto. In other embodiments of the disclosure, the transistors T4(n) and T4a(n) in the border area may also be coupled to the clock signal line CKA or CKB as shown in FIG. 14A, FIG. 15A and FIG. 15B. In other words, in other embodiments of the disclosure, the transistors disposed in the active area and the transistors disposed in the border area may be coupled to the same clock signal line.

Similar to the first embodiment of the first aspect of the disclosure, in the first embodiment of the second aspect of the disclosure, the clock signal lines comprise the first metal layer M1, and as shown in FIG. 13A, the clock signal lines and the gate lines are parallel in the active area. In other embodiments of the disclosure, the clock signal lines may also comprise other metal layer.

FIG. 14A shows a circuit diagram of a plurality of stages of driving units according to a second embodiment of the second aspect of the disclosure. The circuit diagram shown in FIG. 14A is similar to the one shown in FIG. 13A, and only different in that the control electrodes of the transistors T4(n) and T4a(n) in the border area are coupled to the clock line CKB and the control electrodes of the transistors T4(n+1) and T4a(n+1) in the border area are coupled to the clock line CKA. FIG. 14B is a diagram showing signal waveforms according to the second embodiment of the second aspect of the disclosure. Note that the signal waveforms shown in FIG. 14B can also be applied to the circuits shown in FIG. 15A and FIG. 15B.

In the third embodiment of the second aspect of the disclosure, the gate lines of the display panel comprise the first metal layer M1, the data lines comprise the second metal layer M2, and the power line VSS coupled to the voltage source comprises the third metal layer M3. The clock signal lines comprise the second metal layer M2 and the clock signal lines and the data lines are parallel.

FIG. 15A shows a circuit diagram of a plurality of stages of driving units according to a third embodiment of the second aspect of the disclosure. For simplicity, FIG. 15A shows only a portion of the driving units of the gate driver circuit, and the data line numbers 1-5 of data lines D(1)-D(5) are only for illustration, and the disclosure should not be limited thereto.

As shown in FIG. 15A, clock signal lines CKA/CKB and the data lines are parallel and interleaved.

In addition, according to the fourth embodiment of the disclosure, the gate lines of the display panel may comprise the first metal layer M1, the data lines may comprise the second metal layer M2, and the power line VSS coupled to the power source may comprise the third metal layer M3. The clock signal lines may comprise the third metal layer M3 and the clock signal lines spatially overlap the data lines.

FIG. 15B shows a circuit diagram of a plurality of stages of driving units according to a fourth embodiment of the second aspect of the disclosure. For simplicity, FIG. 15B shows only a portion of the driving units of the gate driver circuit, and the data line numbers 1-5 of data lines D(1)-D(5) are only for illustration, and the disclosure should not be limited thereto.

As shown in FIG. 15B, the clock signal lines CKA/CKB and the power line VSS coupled to the power source are parallel and interleaved, and the clock signal lines CKA/CKB spatially overlaps the data line. Note that in order to show the connection points of the transistors and the clock signal lines and the connection points of the transistors and the power lines, in FIG. 13A, FIG. 14A, FIG. 15A and FIG. 15B, the spatially overlapped data lines and power lines, or the spatially overlapped data lines and clock signal lines are drawn separately. However, it should be understood that when the data lines and the power lines, or the data lines and the clock signal lines, comprise different metal layers, the layout of the lines can be spatially overlapped, such that the projection areas thereof can overlap as shown in FIG. 7 and FIG. 8B. In addition, it should be noted that in other embodiments of the disclosure, the layout of the data lines, power lines and clock signal lines which comprise different metal layer may also not spatially overlap. Therefore, the layout of the disclosure should not be limited to the embodiments illustrated above.

In addition, in a fifth embodiment of the second aspect of the disclosure, the number of clock signal lines in the active area may also be increased to be more than two as shown in FIG. 11A, to reduce the duty cycle of the transistors in the active area.

In addition, in a sixth embodiment of the second aspect of the disclosure, when components of the driving unit disposed in the border area are coupled to different clock signal lines as shown in FIG. 13A, the number of clock signals provided to the components disposed in the border area can be increased further to reduce the duty cycle of the transistors in the border area.

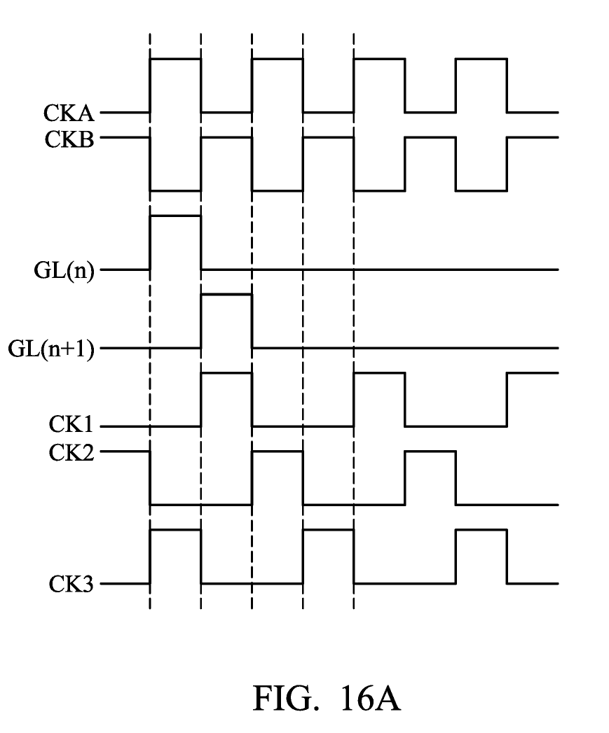

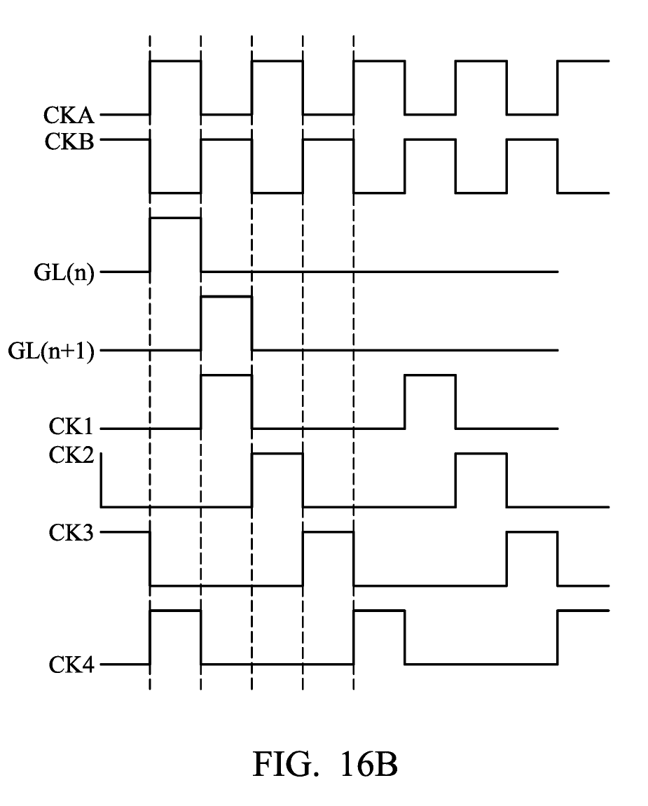

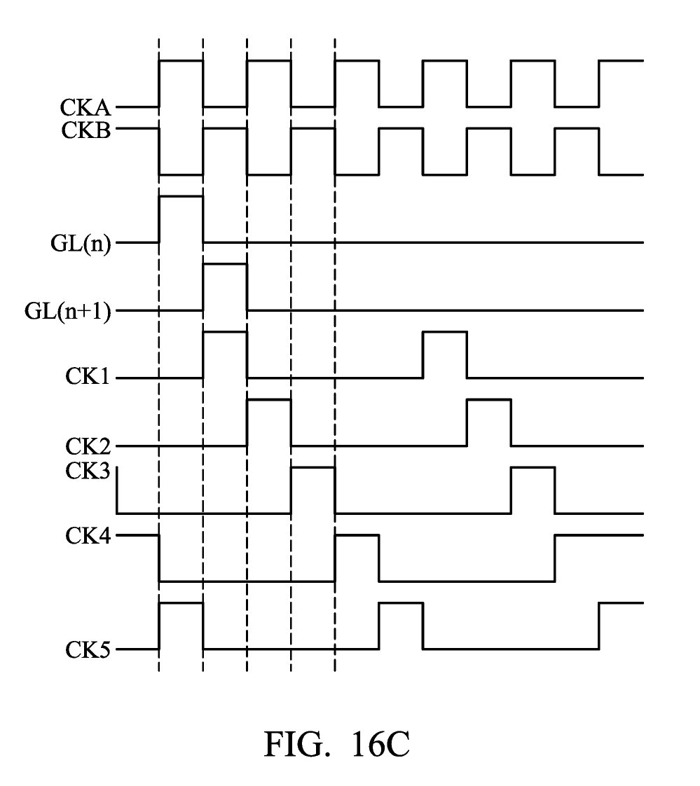

FIG. 16A is a diagram showing signal waveforms according to the sixth embodiment of the second aspect of the disclosure. Compared to the first embodiment of the second aspect of the disclosure shown in FIG. 13A, one more clock signal line CK3 is added in this embodiment. As shown in FIG. 16A, the clock signal lines CK1, CK2 and CK3 sequentially provide non-overlapped clock pulses to the transistors T4 and T4a in different stages. Therefore, compared to the embodiment shown in FIG. 13A, the duty cycle of the transistors (such as the transistors T4 and T4a) disposed in the border area can be reduced from 50% to 33%.

FIG. 16B is another diagram showing signal waveforms according to the sixth embodiment of the second aspect of the disclosure. Compared to the first embodiment of the second aspect of the disclosure shown in FIG. 13A, two clock signal lines CK3 and CK4 are added in this embodiment. As shown in FIG. 16B, the clock signal lines CK1, CK2, CK3 and CK4 sequentially provide non-overlapped clock pulses to the transistors T4 and T4a in different stages. Therefore, compared to the embodiment shown in FIG. 13B, the duty cycle of the transistors (such as the transistors T4 and T4a) disposed in the border area can be reduced from 50% to 25%.

FIG. 16C is yet another diagram showing signal waveforms according to the sixth embodiment of the second aspect of the disclosure. Compared to the first embodiment of the second aspect of the disclosure shown in FIG. 13A, three clock signal lines CK3, CK4 and CK5 are added in this embodiment. As shown in FIG. 16C, the clock signal lines CK1, CK2, CK3, CK4 and CK5 sequentially provide non-overlapped clock pulses to the transistors T4 and T4a in different stages. Therefore, compared to the embodiment shown in FIG. 13B, the duty cycle of the transistors (such as the transistors T4 and T4a) disposed in the border area can be reduced from 50% to 20%.

Therefore, according to the sixth embodiment of the second aspect of the disclosure, the time for the transistors to suffer from the stress of the bias voltage can be reduced, and the reliability of the circuit can be increased.

In the embodiments illustrated above, although the layout of the clock signal lines CKA and CKB are configured horizontally in the active area 200 and the layout of the power lines VSS coupled to the power source are configured vertically in the active area 200, the disclosure should not be limited thereto.

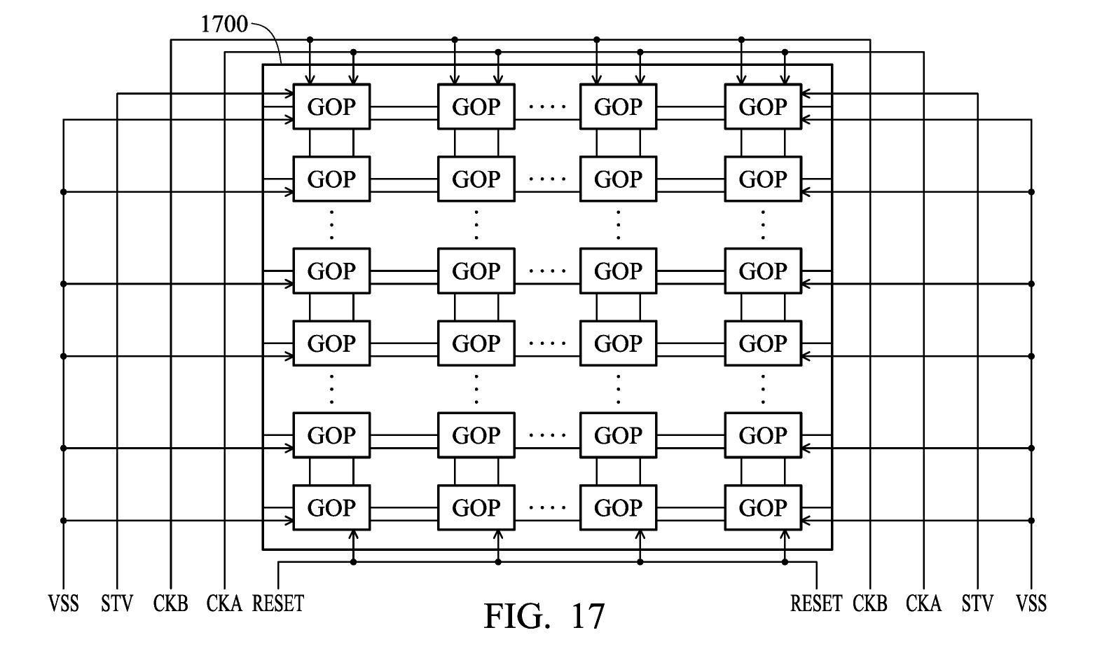

FIG. 17 is a circuit diagram of the gate driver circuit disposed in the active area of the display panel according to another embodiment of the disclosure. As shown in FIG. 17, in this embodiment, the layout of the clock signal lines CKA and CKB are configured vertically in the active area 200 and the layout of the power lines coupled to the power source VSS are configured horizontally in the active area 200.

However, no matter whether the clock signal lines are coupled to the driving units GOP in the active area by horizontal or vertical extension, the degradation of driving ability of the clock signals in the active area due to the parasitic capacitors cannot be avoided, causing serious distortion in the output signals of the gate lines.

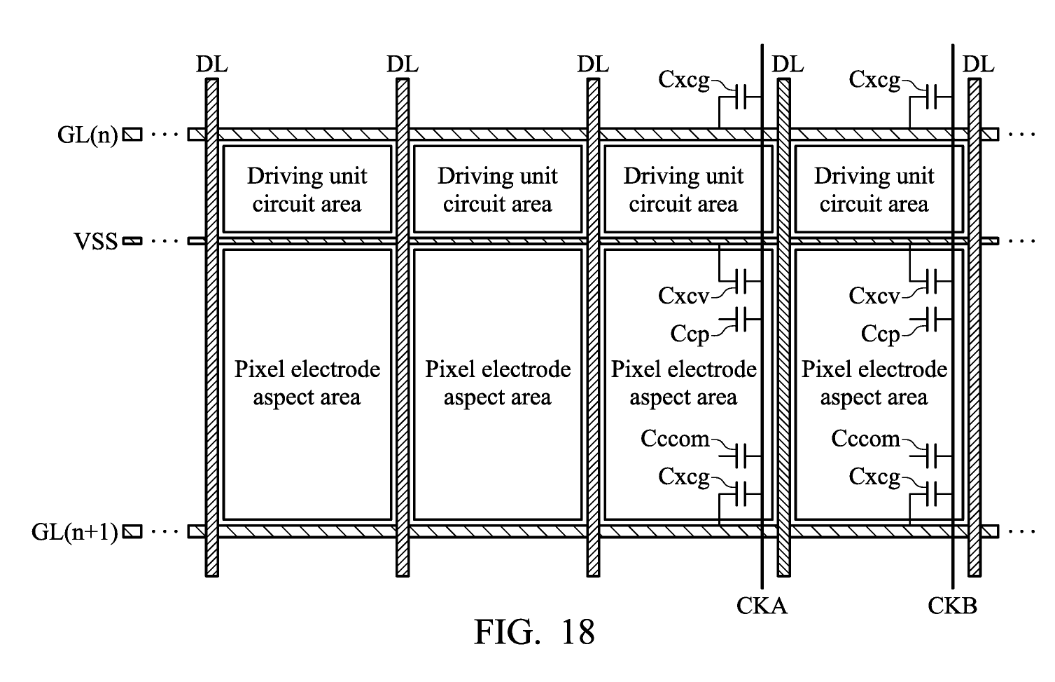

FIG. 18 shows another exemplary top view of the layout of a portion of the pixel array according to another embodiment of the disclosure. As shown in FIG. 18, parasitic capacitor Cxcv will be generated when the clock signal line CKA/CKB crosses the power line VSS, the parasitic capacitor Cxcg will be generated when the clock signal line CKA/CKB crosses the gate lines, the parasitic capacitor Ccp will be generated between the clock signal line CKA/CKB and the pixel electrode when the clock signal line CKA/CKB passes through the aspect area, and the parasitic capacitor Cccom will be generated between the clock signal line CKA/CKB and the common electrode when the clock signal line CKA/CKB passes through the aspect area. As the resolution of the panel increases, the capacitance of the parasitic capacitor increases, degrading the driving ability of the clock signals.

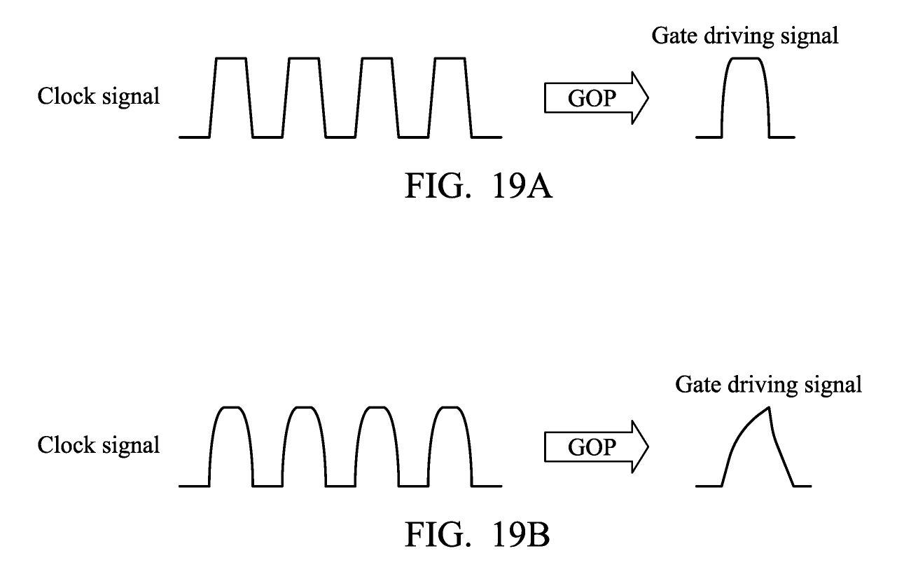

FIG. 19A is an exemplary diagram showing the waveforms of the clock signal and the gate driving signal when the parasitic capacitance is small. FIG. 19B is an exemplary diagram showing the waveforms of the clock signal and the gate driving signal when the parasitic capacitance is large. As shown in the figures, when the parasitic capacitance is large, the driving ability of the clock signals will degrade, causing serious distortion in the gate driving signal.

To solve the problem discussed above, in a third aspect of the disclosure, a novel layout structure for the clock signal lines and a novel configuration for the clock signal timing are proposed, so as to disperse the influence of the parasitic capacitors to the clock signals.

According to the embodiments of the third aspect of the disclosure, the driving unit circuit in the active area is divided into several areas, such as the driving unit circuit area discussed above. The division is not limited to being horizontal or vertical. Each driving unit circuit area has a set of dedicated clock signals for driving the corresponding driving units in that area. For example, in an embodiment of the disclosure, a first driving unit circuit area and a second driving unit circuit area in the active area are driven by different sets of clock signal lines.

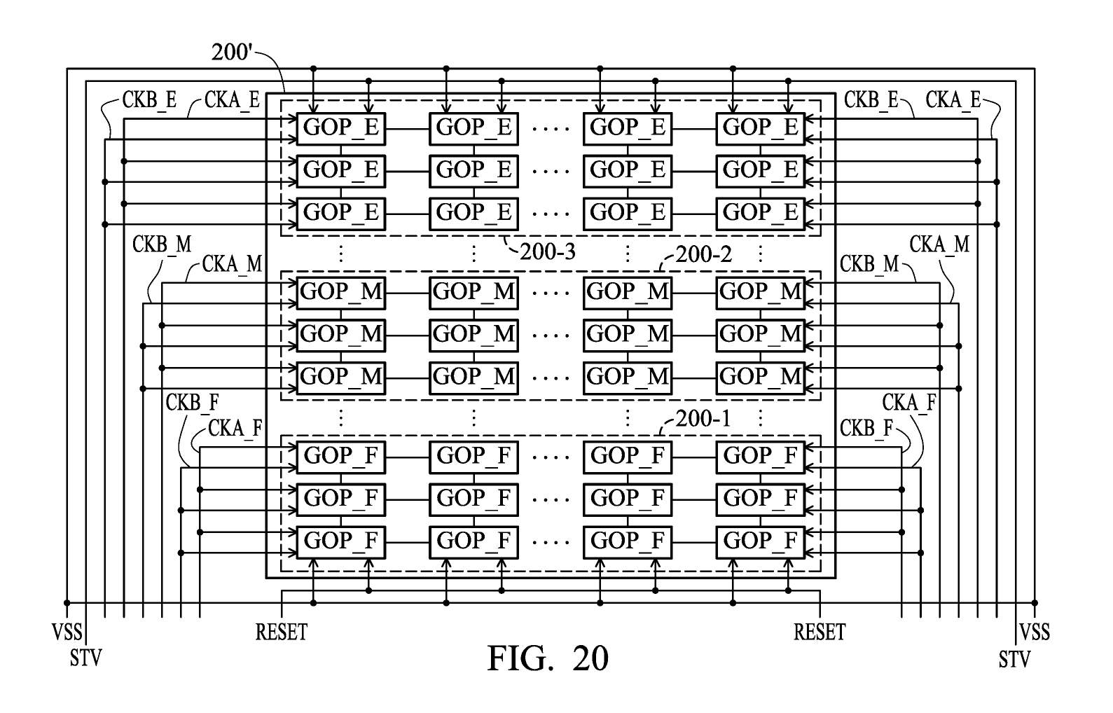

FIG. 20 is a circuit diagram of the gate driver circuit according to a first embodiment of the third aspect of the disclosure. In this embodiment, the driving unit circuit in the active area 200′ may be divided into three areas including the front area, the middle area and the end area. As shown in FIG. 20, the driving unit circuit area 200-1 is the front area comprising the driving units GOP_F, the driving unit circuit area 200-2 is the middle area comprising the driving units GOP_M and the driving unit circuit area 200-3 is the end area comprising the driving units GOP_E. Each driving unit circuit area is driven by different clock signals. For example, the driving unit circuit area 200-1 is driven by a first set of clock signals comprising the clock signals CKA_F and CKB_F, the driving unit circuit area 200-2 is driven by a second set of clock signals comprising the clock signals CKA_M and CKB_M, and the driving unit circuit area 200-3 is driven by a third set of clock signals comprising the clock signals CKA_E and CKB_E, for distributing the parasitic capacitance to the three sets of clock signals.

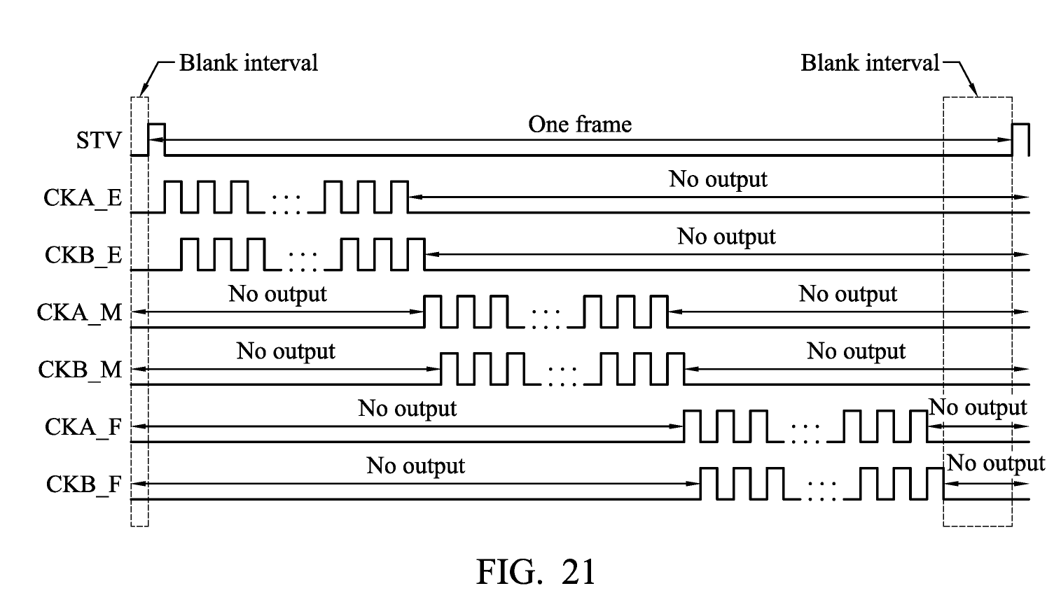

FIG. 21 is an exemplary diagram showing the signal waveforms according to a first embodiment of the third aspect of disclosure. According to the concept of the third aspect of the disclosure, by configuring different sets of clock signals to different driving unit circuit areas, and accompanying them with the timing control of the timing controller chip to provide the clock signals in a time division manner, the influence of the parasitic capacitors to the clock signal lines can be reduced to only one third of the original design.

To be more specific, different sets of clock signals will be arranged to output their clock pulses at different times so as to drive the driving units in the corresponding driving unit circuit area. Take the structure shown in FIG. 20 as an example, three sets of clock signals output clock pulses at different times in a time division manner. During the time interval when the driving units in the driving unit circuit area 200-3 operate, the clock signals CKA_E and CKB_E output their clock pulses. Meanwhile, the statuses of the clock signals CKA_M, CKB_M, CKA_F and CKB_F are “no output”. For example, the voltages of the clock signals CKA_M, CKB_M, CKA_F and CKB_F are pulled down to the voltage level of the reference voltage VGL. When the operation of each stage of driving unit in the driving unit circuit area 200-3 has completed, the driving units in the driving unit circuit area 200-2 operate in sequence. Meanwhile, the clock signals CKA_M and CKB_M output their clock pulses, and the statuses of the clock signals CKA_E and CKB_E become “no output”. For example, the voltages of the clock signals CKA_E, CKB_E, CKA_F and CKB_F are pulled down to the voltage level of the reference voltage VGL. When the operation of each stage of driving unit in the driving unit circuit area 200-2 has completed, the driving units in the driving unit circuit area 200-1 operate in sequence. Meanwhile, the clock signals CKA_F and CKB_F output their clock pulses, and the statuses of the clock signals CKA_M and CKB_M become “no output”. For example, the voltages of the clock signals CKA_E, CKB_E, CKA_M and CKB_M are pulled down to the voltage level of the reference voltage VGL. In this manner, the influence of the parasitic capacitors to the clock signal lines can be reduced only one third of the original designs.

Note that although in the embodiments as discussed, the driving unit circuit is divided into three areas to clearly describe the concepts of the third aspect of the disclosure. The disclosure should not be limited thereto. Those who are skilled in this technology can still make various alterations and modifications without departing from the scope and spirit of this disclosure. For example, one can divide the driving unit circuit into two areas or more than three areas. In addition, the way to divide the driving unit circuit should not be limited to the divide it into the front, middle and end areas or the left, middle and right areas.

In addition, note that although in the embodiments discussed above, each driving unit circuit area is coupled to two clock signal lines for receiving the corresponding clock signals. The disclosure should not be limited thereto. In other embodiments of the disclosure, each driving unit circuit area may be coupled to more than two clock signal lines, such as the driving units GOP shown in FIG. 11A. The driving units in the driving unit circuit area may be respectively coupled to one of the clock signal lines CKA, CKB, CKC and CKD in sequence, and repeated cyclically in this manner, to reduce the duty cycle of the transistors in the active area.

In addition, note that the concept in the third aspect of the disclosure can be not only applied to the gate driver circuit in the first aspect of the disclosure with all the components are disposed in the active area of the display panel, but also can be applied to the gate driver circuit in the second aspect of the disclosure with some components configured in the border area of the display panel, including the embodiment in which the transistors in the border area and the transistors in the active area are coupled to different clock signal lines as shown in FIG. 13A, the embodiments in which the transistors in the border area and the transistors in the active area are coupled to the same clock signal lines as shown in FIG. 14A, 15A and 15B, and the embodiments in which the number of clock signals provided to the transistors in the border area has been increased as shown in FIG. 16A, FIG. 16B and FIG. 16C.

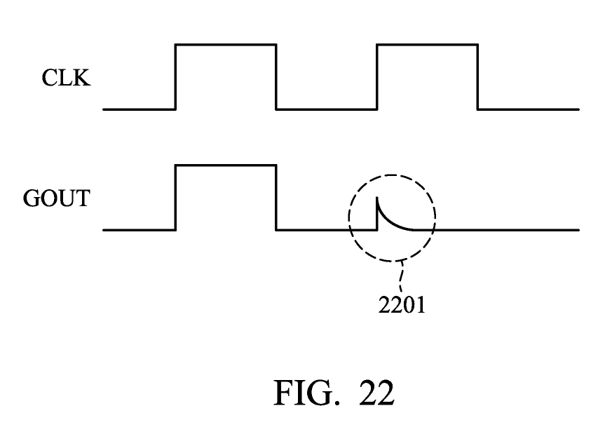

In other words, in the method of controlling the timing of the clock signals in the third aspect of the disclosure, combining the technologies of dividing the clock signals into different sets and arranging each set of clock signals to output clock pulses at different time, each set of clock signals only output when the corresponding driving unit circuit area has to operate, and have no output by setting their voltage to the level of the reference voltage VGL at the remaining time. In this manner, the influence of the parasitic capacitors on the clock signal lines be reduced or power consumption can also be reduced. Or, the time that the transistors suffer from the stress of the bias voltage can be reduced. Or, the reliability of the circuit can be increased. Or, undesired ripples will not be generated at the time when the clock signal has no output. For example, an undesired ripple 2201 output by the gate driving signal GOUT due to the clock pulse at the time when there is no need to generate the gate pulse as shown in FIG. 22 can be avoided.

The disclosure has described several embodiments. And the technical features described in those embodiments can be picked, selected, and mixed to form another embodiment.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

While the disclosure has been described by way of example and in terms of several embodiments, it is to be understood that the disclosure is not limited thereto. Those who are skilled in this technology can still make various alterations and modifications without departing from the scope and spirit of this disclosure. Therefore, the scope of the present disclosure shall be defined and protected by the following claims and their equivalents.

What is claimed is:

1. A display panel, comprising:
a substrate;
a plurality of data lines;
a plurality of gate lines;
a power line, coupled to a power source; and
a gate driver circuit, disposed in an active area of the substrate and coupled to the gate lines and the power line, and generating a plurality of gate driving signals in response to a start pulse,
wherein the gate lines comprise a first metal layer which is disposed above the substrate, the data lines comprise a second metal layer which is disposed above the first metal layer, the power line comprises a third metal layer which is disposed above the second metal layer, and an orthogonal projection of at least one of the data lines onto the substrate overlaps an orthogonal projection of the power line onto the substrate.

2. The display panel as claimed in claim 1, further comprising a plurality of clock signal lines, coupled to the gate driver circuit, for providing a plurality of clock signals, wherein the clock signal lines comprise the first metal layer and the clock signal lines and the gate lines are parallel.

3. The display panel as claimed in claim 1, further comprising a plurality of clock signal lines, coupled to the gate driver circuit, for providing a plurality of clock signals, wherein the clock signal lines comprise the second metal layer and the clock signal lines and the data lines are parallel.

4. The display panel as claimed in claim 1, further comprising a plurality of clock signal lines, coupled to the gate driver circuit, for providing a plurality of clock signals, wherein the clock signal lines comprise the third metal layer and the clock signal lines and the power line are parallel, and an orthogonal projection of at least one of the data lines onto the substrate overlaps an orthogonal projection of at least one of the clock signal lines onto the substrate.

5. The display panel as claimed in claim 1, further comprising a plurality of clock signal lines, wherein the number of the plurality of clock signal lines is more than three, and the plurality of clock signal lines respectively provide non-overlapped clock pulses in sequence.

6. The display panel as claimed in claim 1, further comprising a plurality of clock signal lines, wherein the plurality of clock signal lines are divided into plural sets of clock signal lines, and the plural sets of clock signal lines are arranged to output clock pulses at different times.

7. The display panel as claimed in claim 6, wherein the gate driver circuit in the active area of the substrate is divided plural circuit area, and the plural circuit area are respectively driven by the plural sets of clock signal lines.

8. The display panel as claimed in claim 1, further comprising a touch sensing electrode, wherein the touch sensing electrode is electrically connected to the power line.

9. The display panel as claimed in claim 1, wherein the gate driver circuit comprises N stages of driving units, and wherein an n-th stage driving unit comprises:
a first transistor, comprising a first electrode coupled to a first clock signal line and a second electrode coupled to an n-th gate line;
a second transistor, comprising a control electrode and a first electrode coupled to an (n−1)-th gate line and a second electrode coupled to a control electrode of the first transistor; and
a third transistor, comprising a control electrode coupled to an (n+1)-th gate line, a first electrode coupled to the second electrode of the second transistor and a second electrode coupled to the power line,
wherein n and N are positive integers, and 0<n≦N.

10. The display panel as claimed in claim 9, wherein the n-th stage driving unit further comprises:
a fourth transistor, comprising a control electrode coupled to a second clock signal line, a first electrode coupled to the n-th gate line and a second electrode coupled to the power line.

11. The display panel as claimed in claim 9, further comprising:
a fourth transistor, comprising a control electrode coupled to a second clock signal line, a first electrode coupled to the n-th gate line and a second electrode coupled to the power line,
wherein the fourth transistor is disposed in a border area of the substrate, and wherein the border area is adjacent to the active area.

12. A display panel, comprising:
a substrate
a plurality of gate lines;
a plurality of data lines;
a plurality of clock signal lines, providing a plurality of clock signals; and
a gate driver circuit, disposed in an active area of the substrate, coupled to the gate lines and the clock signal lines, and generating a plurality of gate driving signals in response to a start pulse,
wherein the gate lines and the clock signal lines comprise a first metal layer which layer which is disposed above the first metal layer, and the gate lines and the clock signal lines are parallel.

13. The display panel as claimed in claim 12, further comprising:
a power line, coupled to a power source; and
wherein the power line comprises a third metal layer, the third metal layer is disposed above the second metal layer, and an orthogonal projection of at least one of the data lines onto the substrate overlaps an orthogonal projection of the power line onto the substrate.

14. The display panel as claimed in claim 12, wherein a number of the plurality of clock signal lines is more than three, and the plurality of clock signal lines respectively provide non-overlapped clock pulses in sequence.

15. The display panel as claimed in claim 12, further comprising a plurality of clock signal lines, wherein the plurality of clock signal lines are divided into plural sets of clock signal lines, and the plural sets of clock signal lines are arranged to output clock pulses at different times.

16. The display panel as claimed in claim 15, wherein the gate driver circuit in the active area of the substrate is divided plural circuit area, and the plural circuit area are driven by the plural sets of clock signal lines.

17. The display panel as claimed in claim 12, further comprising a touch sensing electrode, wherein the touch sensing electrode is electrically connected to the power line.

18. The display panel as claimed in claim 12, wherein the gate driver circuit comprises N stages of driving units, and wherein an n-th stage driving unit comprises:
a first transistor, comprising a first electrode coupled to a first clock signal line and a second electrode coupled to an n-th gate line;
a second transistor, comprising a control electrode and a first electrode coupled to an (n−1)-th gate line and a second electrode coupled to a control electrode of the first transistor; and
a third transistor, comprising a control electrode coupled to an (n+1)-th gate line, a first electrode coupled to the second electrode of the second transistor and a second electrode coupled to the power line,
wherein n and N are positive integers, and 0<n≦N.

19. The display panel as claimed in claim 18, wherein the n-th stage driving unit further comprises:
a fourth transistor, comprising a control electrode coupled to a second clock signal line, a first electrode coupled to the n-th gate line and a second electrode coupled to the power line.

20. The display panel as claimed in claim 18, further comprising:
a fourth transistor, comprising a control electrode coupled to a second clock signal line, a first electrode coupled to the n-th gate line and a second electrode coupled to the power line,
wherein the fourth transistor is disposed in a border area of the substrate, and wherein the border area is adjacent to the active area.
